(19) United States
(12) Patent Application Publication
(10) Pub. No.: US 2026/0180835 A1
(43) Pub. Date: Jun. 25, 2026

(54) DISPLAY DRIVING CHIP INSENSITIVE TO TEMPERATURE CHANGE AND OPERATION METHOD THEREOF

(71) Applicant: LX SEMICON CO., LTD., Daejeon (KR)

(72) Inventor: Young Bok KIM, Daejeon (KR)

(73) Assignee: LX SEMICON CO., LTD., Daejeon (KR)

(21) Appl. No.: 19/126,863

(22) PCT Filed: Jun. 27, 2023
(86) PCT No.: PCT/KR2023/008884

§ 371 Date: May 2, 2025

(30) Foreign Application Priority Data
Nov. 3, 2022 (KR) 10-2022-0145436

(51) Int. Cl. H04L 25/03; G09G 3/20; G09G 3/3275; G09G 3/36; H04L 25/02

(52) U.S. Cl. CPC H04L 25/03057; G09G 3/20; G09G 3/3275; G09G 3/3648; G09G 3/3688; H04L 25/0272; H04L 25/03019; H04L 25/03885; G09G 5/008; G09G 2310/0297; G09G 2370/08; H10W 44/00; H10W 44/401; H10W 44/601

(57) ABSTRACT

The present invention relates to a driving chip which enables high-quality image data to be adaptively provided to a display device according to a temperature change, and an operation method thereof, wherein the driving chip may comprise: an impedance matching circuit which minimizes distortion of an input data signal; an equalization circuit which compensates for loss of the input data signal; a clock data recovery circuit which reconstructs an output of the equalization circuit to match a clock signal; a reordering circuit which reorders the reconstructed data for each channel; and a temperature control circuit which generates a plurality of control signals according to a temperature change.

### TECHNICAL FIELD

The present invention relates to a display driver chip and a method for operating the display driver chip, which detect a temperature change and enable an operating condition of the driver chip to be changed accordingly to minimize a change in an operating characteristic of the display driver chip resulting from the temperature change.

### BACKGROUND ART

Data transmission is one of the important functions of integrated circuit devices. With the development of integrated circuit technology, the speed of data transmission has gradually increased. In particular, as the technology for wired or wirelessly data transmission approaches the gigahertz (GHz) range, it has become necessary for the integrated circuits that transmit or receive wireless data to also be able to handle data with frequency bands in the gigahertz range. When high-frequency band signals are input to a receiving end of an integrated circuit, matching between the input signal and the impedance of the input node is required, and this requirement increases as the frequency increases. If impedance matching is not performed properly at the receiving end, the signal input to the receiving end will eventually be distorted as the bandwidth is reduced by signal reflections at the termination, and the signal will be lost as much as it is distorted.

As display screens trend to become larger and higher in resolution, signal distortion issues also arise between a timing controller and a display driver chip. These issues stem from increased channel impedance due to longer data buses and signal reflection at the termination due to higher speeds.

To minimize these issues, the impedance matching circuit within the display driver chip is configured with an optimum impedance value determined for impedance matching.

However, when the operating temperature of the display driver chip changes or the temperature environment around the board on which the driver chip is mounted changes, the impedance value also varies, and the current of the MOS transistor also varies due to temperature dependence. These temperature changes lead to impedance matching imbalances and incomplete signal equalization, causing distortion or loss of the image data signal. Consequently, the quality of the image data signal transmitted by the driver chip to the display device degrades, resulting in reduced display performance.

### DISCLOSURE

### Technical Problem

A technical problem to be solved by the present invention is to allow various controllable operating conditions to be set in a display driver chip to prevent changes in the operating condition of the display driver caused by temperature change.

Another technical problem to be solved by the present invention is to provide a device and a method capable of preventing from the deterioration of image quality of the display driver chip due to changes in the operating condition of the display driver chip caused by temperature change.

According to another embodiment of the present invention to address the above problems, there is provided a display driver chip insensitive to temperature, which includes: an impedance matching circuit configured to minimize distortion of an input data signal; an equalization circuit configured to compensate for the loss of the input data signal; a clock data recovery circuit configured to recover the output of the equalization circuit to match a clock signal; a reordering circuit configured to reorder the recovered data per channel; and a temperature control circuit configured to generate a plurality of control signals in response to temperature change.

According to another embodiment of the present invention to address the above problems, there is provided a method of operating a display driver chip, which includes: applying a power supply voltage or a power-on reset to start the operation of the display driver chip; detecting temperature change; adjusting at least some of an initial impedance value, an initial gain value, and an initial bias value if there is temperature change as a result of the detection; and recovering image data.

According to the present invention, there is an effect that the display driver chip may exhibit constant performance despite the change in the ambient temperature surrounding the display driver chip or the change in the operating temperature caused by the operation of the driver chip.

According to the present invention, there is an effect that the display driver chip may provide image data of a constant quality to the display device even when the temperature change.

### BRIEF DESCRIPTION OF THE SEVERAL VIEWS OF THE DRAWINGS

FIG. 1 is a block diagram of a circuit according to one embodiment of the present invention.

FIG. 2 is a partial block diagram according to one embodiment of the present invention.

FIG. 3 illustrates a partial circuit according to one embodiment of the present invention.

FIG. 4 illustrates another partial circuit according to one embodiment of the present invention.

FIG. 5 illustrates a method of operation of the present invention.

### MODE OF PRACTING THE INVENTION

Before describing the present invention, a brief explanation of the technical terms and abbreviations frequently used in the present invention is provided to help understand them. This description makes it possible to more easily understand the technical idea of the present invention. First, throughout the specification of the present invention, it should be noted that the meanings of the terms chip, integrated circuit (IC), circuit, circuitry, or unit may be used as interchangeable meanings, and may or may not necessarily mean individually packaged configurations, and the meanings of such terms should be interpreted based on the description of the technical content. In addition, “data” herein means “image data”.

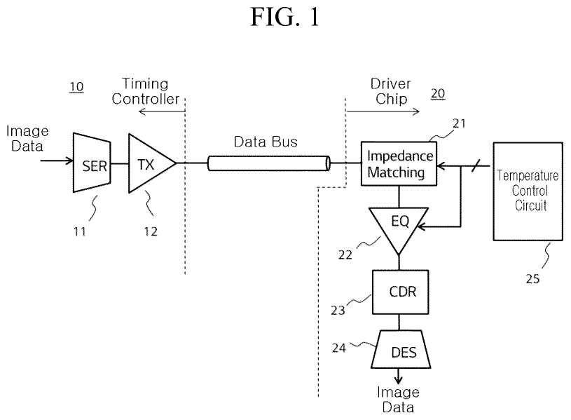

As shown in FIG. 1, a timing controller 10 refers to a semiconductor chip or circuit, also known as a T-CON, which is a configuration that transmits display data or controls its timing so that a driver chip 20 or a driving circuit may properly receive the display data. A source driver integrated circuit SDIC refers to a semiconductor integrated circuit (IC) that drives the source direction of pixels constituting a display panel. In some cases, the source driver chip SDIC may mean an IC in which a readout function that detects and transmits touch signals to a touch IC is incorporated in addition to the source driving function. Hereinafter, the present invention is described for the source driver chip as an example; however the present invention is applicable to any driver chip that transmits image data to a display. For reference, the same reference numerals refer to the same components.

The optimal equalization function that takes place inside the display driver chip to recover the signal is achieved by performing an auto-equalization that automatically executes before each frame data arrives. For other optimal equalization functions, when the source driver chip is initialized by applying a power voltage (Power On) or receiving a power-on reset (POR) signal, it first automatically sets an initial equalization interval in its non-driving state, performs a scan of on all applicable equalization steps during the initial equalization interval, and then determines the value of the optimal equalization step and additional equalization steps based on the scan result. The determined optimal equalization step is used during the vertical blank (V-Blank) interval.

In the following, a circuit configuration illustrating one embodiment of the present invention implementing these features will be described with reference to FIG. 1. The display driver chip 20 of the present invention includes an impedance matching circuit 21, an equalization (EQ) circuit 22 for compensating the image data transmitted from the timing controller 10 without loss, a clock data recovery (CDR) circuit 23, a reordering circuit (DESerializer) 24 for reordering the serial image data per channel, and a temperature control circuit 25 for controlling the conditions of the impedance matching and equalization according to changes in temperature.

The output of the reordering circuit 24 may be composed of multiple channels, and in some cases, may be three channel data representing three primary colors (RGB (Red Green Blue)).

The clock data recovery (CDR) circuit is a circuit that recovers received data signals so that the received data signals retain their original waveforms or are well synchronized with each clock signal. For ease of description, the clock signal is not depicted separately in the specification of the present invention.

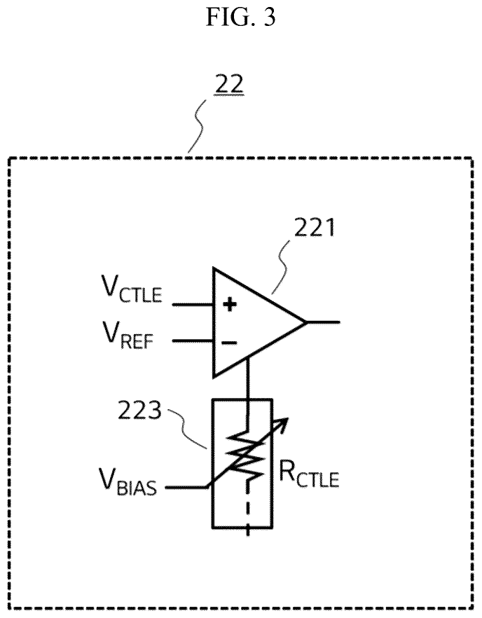

The equalization circuit 22 may primarily use a continuous time linear equalizer (CTLE) to allow for tracking of the input data in real time, and the continuous time linear equalizer may include an amplifier 221 and a bias circuit 223 for linear amplification operation of the amplifier, as illustrated in FIG. 3.

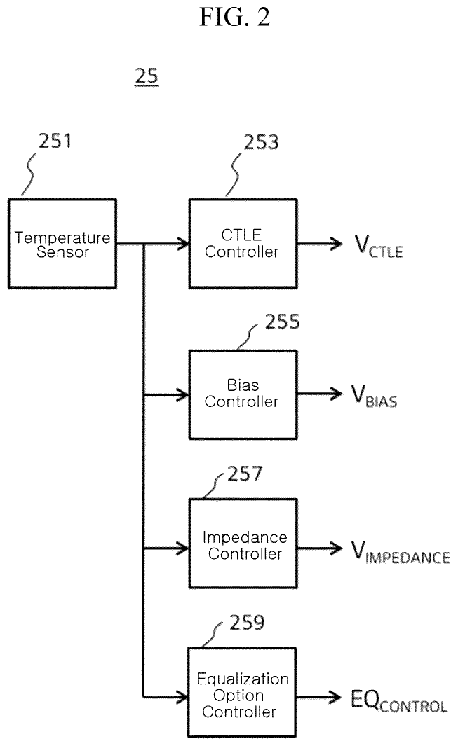

FIG. 2 illustrates the internal configuration of the temperature control circuit 25 in more detail. The temperature control circuit 25 includes a temperature sensor 251 for detecting temperature, a continuous time linear equalizer (CTLE) controller 253 for controlling the operation of the equalization circuit 22 based on the detected temperature, a bias controller 255, and an impedance controller 257 for controlling the impedance of the impedance matching circuit 21. If necessary, an equalization option controls 259 may also be included to allow the equalization conditions to vary with temperature change.

The amplifier 221 included in the equalization circuit 22 may function not just as an amplifier, but as a comparator that compares two input voltages and outputs an output proportional to the value of the difference between them. Of the two input voltages, VREF, is a reference voltage, which is the voltage that is generated independent of temperature change, e.g., as in a band gap reference (BGR) circuit. The other of the two input voltages, VCTLE, is a control signal provided by the CTLE controller 253, which may be varied to make the characteristics of the amplifier 221 forming the equalization circuit 22 insensitive to temperature change. For example, as the operating temperature of the driver chip increases or decreases from the initially set temperature, the voltage VCTLE also increases or decreases in response, thereby changing the gain of the amplifier 221 to offset the change in the characteristic of the equalization circuit 22 due to the temperature change.

In the configuration of the temperature control circuit 25, the control signal VBIAS generated by the bias controller 255 is a signal for varying the bias of the continuous time linear equalization circuit 22 in response to temperature change. Here, the value of the passive bias element 223, denoted as RCTLE, is varied to ensure that the operating conditions of the continuous time linear equalization circuit 22 always result in optimal equalization. Although the passive bias element 223 is denoted as RCTLE in FIG. 3 for simplicity of illustration, it is understood that various passive elements may be used in combination.

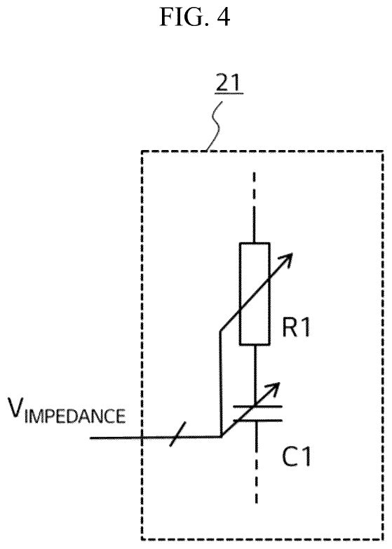

FIG. 4 illustrates by way of example some of the elements constituting the impedance matching circuit 21. There are many possible combinations or connections of these elements, but for simplicity of illustration, they are simply shown here as a series connection of a resistor R1 and a capacitor C1. The impedance controller 257 generates a control signal VIMPEDANCE to vary the impedance of the impedance matching circuit 21 in response to temperature change. An initial impedance value of the impedance matching circuit 21 is predetermined by the designer's efforts. The impedance matching circuit 21 typically comprises a combination of passive elements such as resistors or capacitors, and in some cases, active elements such as transistors may be used in place of some of the passive elements. Regardless of whether passive or active elements, as the operating temperature changes, the value of the elements changes according to the inherent temperature coefficients of the elements. For example, for diffusion resistors, which are passive elements formed through the diffusion technique of semiconductor impurities, if the temperature coefficient has a positive (+) value, the value of the diffusion resistors also increases as the temperature increases. As an active element, a transistor is also sensitive to temperature change. For example, the drain current of a MOS transistor is proportional to the −1.5 square of the temperature. It is already well known that this is due to the temperature dependence of the mobility of the transistor. Therefore, the current of the transistor, which decreases as temperature increases, may be compensated for by appropriate calculations.

As described above, to summarize the operation of the impedance controller 257, the impedance controller 257 dynamically adjusts the initial impedance value of the impedance matching circuit 21 using a control signal VIMPEDANCE that corresponds to temperature change, thereby minimizing distortion of the input data signal.

The temperature control functions of the temperature control circuit 25 described above are preferably operate effectively when the ambient temperature surrounding the display driver chip 20 or the operating temperature of the driver chip changes from the reference temperature. The reference temperature here may be preset to a room temperature, for example, 25 degrees Celsius. Assuming this reference temperature, the initial impedance value of the impedance matching circuit 21, the number of initial equalization steps of the equalization circuit 22, the initial bias value of the amplifier included in the equalization circuit 22, and the like may be reflected in advance in the process of the initial circuit design.

As described above, the equalization option controller 259 may be additionally included in the temperature control circuit 25. The equalization option controller 259 is a circuit in charge of all the overall control of equalization, including setting various conditions for initial equalization (Initial EQ), making decisions about the optimal equalization steps and additional equalization steps, and the like. The equalization option controller 259 may additionally increase or decrease the equalization steps in response to temperature change. For example, it may add an additional equalization step based on temperature change to the optimal equalization step. The additional equalization step may be increased or decreased by an integer multiple of the optimal equalization step.

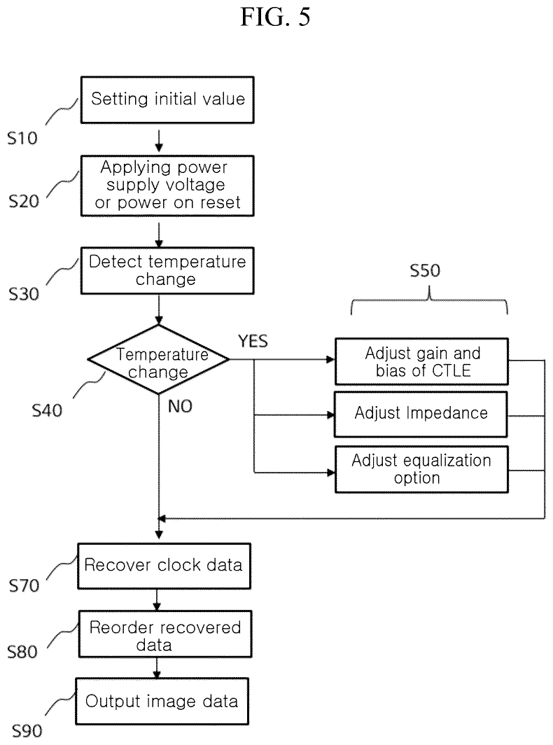

From the above-described technical ideas of the present invention, a method of controlling the display driver chip insensitive to temperature change may be summarized in the following steps, as shown in FIG. 5. First, assuming a normal temperature operation, the initial impedance value of the impedance matching circuit 21, the initial gain value of the equalization circuit 21, and the initial bias value are carefully calculated by design, and then the initial values are set in advance (step S10). When a power supply voltage is applied or a power-on reset signal is received, the display driver chip starts operation (step S20). The display driver chip detects ambient temperature change during operation (step S30). If there is a temperature change, the gain and bias of the equalization circuit is adjusted (step S50), and the control proceeds to the next step (step S70). If there is no temperature change, the image data is recovered to match the clock signal (step S70). The recovered image data is reordered per channel (step S80), and the reordered image data is output to the display device (step S90). Here, the adjustment of step S50 may further include adjusting an equalization option of the equalization circuit. The equalization option may include at least some of an initial equalization, an auto-equalization, an optimal equalization step, and an additional equalization step.

In this way, even if there are changes in the ambient environment surrounding the display driver chip, such as change in the power supply voltage, change in the operating temperature, etc., change in the operating characteristics of the driver chip may be minimized. As a result, it is possible to transmit error-free image data from the driver chip to the display device, which in turn ensures consistent image quality on the display screen. The present invention, although described using the source driver chip as an example, may be applied to any type of display driver chips, and may be implemented regardless of the type of display devices, including LCD or OLED.

1. A display driver chip insensitive to temperature comprising:
an impedance matching circuit configured to minimize distortion of an input data signal;
an equalization circuit configured to compensate for the loss of the input data signal;
a clock data recovery circuit configured to recover the output of the equalization circuit to match a clock signal;
a reordering circuit configured to reorder the recovered data by channel; and
a temperature control circuit configured to generate a plurality of control signals in response to temperature change.

2. The display driver chip of claim 1, wherein the temperature control circuit includes:
a continuous time linear equalizer controller configured to control an equalization condition of the input data; a bias controller configured to control a bias value included in the equalization circuit; and an impedance controller configured to control an impedance value of the impedance matching circuit.

3. The display driver chip of claim 2, wherein the temperature control circuit further includes:
an equalization option controller configured to control an initial equalization, an optimal equalization step, and an additional equalization step.

4. The display driver chip of claim 1, wherein the temperature control circuit is configured to dynamically adjust the impedance value of the impedance matching circuit in response to temperature change.

5. The display driver chip of claim 1, wherein the temperature control circuit is configured to operate when the operating temperature of the display driver chip or the ambient temperature of the display driver chip changes from a preset reference temperature.

6. The display driver chip of claim 1, wherein the equalization circuit is configured to add an integer multiple of additional equalization steps to the initial equalization value as the temperature changes.

7. The display driver chip of claim 2, wherein the continuous time linear equalizer controller is configured to adjust the gain of the equalization circuit as the temperature changes.

8. The display driver chip of claim 2, wherein the continuous time linear equalizer controller is configured to adjust the bias of the equalization circuit as the temperature changes.

9. The display driver chip of claim 1, wherein the optimal equalization value of the equalization circuit is used during a vertical blank interval between frames of data constituting image data.

10. The display driver chip of claim 1, wherein the impedance matching circuit includes passive elements including a resistors and a capacitor.

11. The display driver chip of claim 1, wherein the impedance matching circuit includes an active element including a transistor.

12. A method of operating a display driver chip, comprising:
applying a power supply voltage or a power-on reset to start the operation of the display driver chip;
detecting temperature change;
adjusting at least some of an initial impedance value, an initial gain value, and an initial bias value if there is temperature change as a result of the detection; and
recovering image data.

13. The method of claim 12, wherein said adjusting further includes:
at least some of an initial equalization or auto-equalization executed prior to receiving the input data, an optimal equalization step executed between frames of data, and additional equalization steps.

14. The method of claim 13, wherein the number of the additional equalization steps is determined after scanning the initial equalization or auto-equalization, based on the results of this scan.

15. The method of claim 6, wherein the additional equalization steps are increased or decreased by an integer multiple of the optimal equalization step.

16. The method of claim 13, wherein the optimal equalization step is used during a vertical blank interval between frames of data constituting the image data.
